(19) United States
(12) Patent Application Publication
(10) Pub. No.: US 2010/0307360 A1
(43) Pub. Date: Dec. 9, 2010

(54) METHOD FOR MAKING A LITHOGRAPHIC PRINTING PLATE PRECURSOR

(75) Inventors: Hieronymus Andriessen, Beerse (BE); Paola Campestrini, Antwerpen (BE); Roberto Gaggiano, Conegliano Veneto (IT)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: Agfa Graphics NV, Mortsel (BE)

(21) Appl. No.: 12/531,790

(22) PCT Filed: Mar. 12, 2008
(86) PCT No.: PCT/EP08/52904

§ 371 Date: Aug. 24, 2010

Related U.S. Application Data
(60) Provisional application No. 60/896,305, filed on Mar. 22, 2007.

(30) Foreign Application Priority Data
Mar. 20, 2007 (EP) 07104472.1

(51) Int. Cl. B41N 3/03; G03F 7/004; G03F 7/20

(52) U.S. Cl. 101/463.1; 430/270.1; 430/302

(57) ABSTRACT

A method for making a lithographic printing plate precursor comprising the steps of: (i) providing a grained and anodized aluminum support; (ii) treating the support with an aqueous solution comprising a salt of zirconium; (iii) treating the support with an aqueous solution comprising a compound comprising a phosphonic acid group and/or an ester or a salt thereof; (iv) applying a coating comprising hydrophobic particles and a binder; (v) drying said coating.

### FIELD OF THE INVENTION

The present invention relates to a method for making a heat- and/or light sensitive, lithographic printing plate precursor.

### BACKGROUND OF THE INVENTION

Lithographic printing presses use a so-called printing master such as a printing plate which is mounted on a cylinder of the printing press. The master carries a lithographic image on its surface and a print is obtained by applying ink to said image and then transferring the ink from the master onto a receiver material, which is typically paper. In conventional, so-called “wet” lithographic printing, ink as well as an aqueous fountain solution (also called dampening liquid) are supplied to the lithographic image which consists of oleophilic (or hydrophobic, i.e. ink-accepting, water-repelling) areas as well as hydrophilic (or oleophobic, i.e. water-accepting, ink-repelling) areas. In so-called driographic printing, the lithographic image consists of ink-accepting and ink-abhesive (ink-repelling) areas and during driographic printing, only ink is supplied to the master.

Printing masters are generally obtained by the image-wise exposure and processing of an imaging material called plate precursor. In addition to the well-known photosensitive, so-called pre-sensitized plates, which are suitable for UV contact exposure through a film mask, also heat-sensitive printing plate precursors have become very popular in the late 1990s. Such thermal materials offer the advantage of daylight stability and are especially used in the so-called computer-to-plate method wherein the plate precursor is directly exposed, i.e. without the use of a film mask. The material is exposed to heat or to infrared light and the generated heat triggers a (physico-)chemical process, such as ablation, polymerization, insolubilization by cross linking of a polymer, heat-induced solubilization, or by particle coagulation of a thermoplastic polymer latex.

The most popular thermal plates form an image by a heat-induced solubility difference in an alkaline developer between exposed and non-exposed areas of the coating. The coating typically comprises an oleophilic binder, e.g. a phenolic resin, of which the rate of dissolution in the developer is either reduced (negative working) or increased (positive working) by the image-wise exposure. During processing, the solubility differential leads to the removal of the non-image (non-printing) areas of the coating, thereby revealing the hydrophilic support, while the image (printing) areas of the coating remain on the support. Typical examples of such plates are described in e.g. EP-A 625728, 823327, 825927, 864420, 894622 and 901902. Negative working embodiments of such thermal materials often require a pre-heat step between exposure and development as described in e.g. EP-A 625,728.

Negative working plate precursors which do not require a pre-heat step may contain an image-recording layer that works by heat-induced particle coalescence of a thermoplastic polymer particle (latex), as described in e.g. EP-As 770 494, 770 495, 770 496 and 770 497. These patents disclose a method for making a lithographic printing plate comprising the steps of (1) image-wise exposing an imaging element comprising hydrophobic thermoplastic polymer particles dispersed in a hydrophilic binder and a compound capable of converting light into heat, (2) and developing the image-wise exposed element by applying fountain and/or ink.

Some of these thermal processes enable plate making without wet processing and are for example based on ablation of one or more layers of the coating. At the exposed areas the surface of an underlying layer is revealed which has a different affinity towards ink or fountain than the surface of the unexposed coating.

Other thermal processes which enable plate making without wet processing are for example processes based on a heat-induced hydrophilic/oleophilic conversion of one or more layers of the coating so that at exposed areas a different affinity towards ink or fountain is created than at the surface of the unexposed coating.

EP-A 1 614 538 describes a negative working lithographic printing plate precursor which comprises a support having a hydrophilic surface or which is provided with a hydrophilic layer and a coating provided thereon, the coating comprising an image-recording layer which includes hydrophobic thermoplastic polymer particles and a hydrophilic binder, characterised in that the hydrophobic thermoplastic polymer particles have an average particle size in the range from 45 nm to 63 nm, and that the amount of the hydrophobic thermoplastic polymer particles in the image-recording layer is at least 70%, by weight relative to the image-recording layer.

EP-A 1 614 539 and EP-A 1 614 540 describe a method of making a lithographic printing plate comprising the steps of (1) image-wise exposing an imaging element disclosed in EP-A 1 614 538 and (2) developing the image-wise exposed element by applying an aqueous, alkaline solution.

WO2006/037716 describes a method for preparing a negative-working lithographic printing plate which comprises the steps of (1) image-wise exposing an imaging element comprising hydrophobic thermoplastic polymer particles dispersed in a hydrophilic binder and a compound capable of converting light into heat and (2) developing the image-wise exposed element by applying a gum solution; characterised in that the average particle size of the thermoplastic polymer particles ranges between 40 nm and 63 nm and wherein the amount of the hydrophobic thermoplastic polymer particles is more than 70% and less than 85% by weight relative to the image recording layer.

The unpublished European Patent Application EP-A 06 114 473 (filed on 24, May 2006) disclose a printing plate precursor comprising thermoplastic polymer particles having an average particle size of less than 40 nm and an infrared light absorbing dye in an amount, without taking into account an optional counterion, of more than 0.80 mg per m² of the total surface of the hydrophobic particles.

Unpublished EP-A 06 122 415 (filed 17-Oct.-2006) discloses a heat-sensitive negative-working lithographic printing plate precursor comprising on a support an image-recording layer comprising hydrophobic thermoplastic polymer particles, an infrared light absorbing dye and a compound comprising an aromatic moiety and at least one acidic group or salt thereof and having a most bathochromic light absorption peak at a wavelength between 300 nm and 450 nm. Unpublished EP-A 06 122 423 (filed 17, Oct. 2006) discloses a heat-sensitive negative-working lithographic printing plate precursor comprising on a support an image-recording layer comprising hydrophobic thermoplastic polymer particles, an infrared light absorbing dye and a dye with a specified structure and a most bathochromic light absorption peak between 451 nm and 750 nm.

EP 1 247 644 discloses a lithographic printing plate comprising a support which is subjected to a hydrophilic surface treatment by dipping it in an aqueous solution containing one or more hydrophilic compounds selected from compounds having a polyvinyl phosphonic acid or a sulfonic acid group, sugar compounds or silicate compounds. Alternatively, a solution comprising an alkali metal silicate, zirconium potassium fluoride or a mixture of a phosphate and an inorganic fluoro compound, may be used.

EP 1 142 707 discloses a method whereby the density of micropores present at the anodic oxidation layer of a grained and anodized aluminum support is controlled by specific treatments such as treating the support in an aqueous acid or alkali solution (a pore widening treatment) which may be followed by a treatment with a hydrophylic compound such as polyvinylphosphonic acid, compounds containing sulfonic acid groups, and saccharide compounds. After the pore widening treatment, a pore sealing treatment may be carried out.

EP 1 176 031 discloses a method for making a lithographic printing plate substrate comprising the steps of treating a grained and anodized substrate with an aqueous solution comprising a salt of a metal from Group IB, IIB, IVA, IVB, VB, VIIA, VIIB, VIIB or VIII of the Periodic Table followed by a treatment with an aqueous solution comprising an orthophosphate salt of an alkali metal.

A major problem associated with negative-working printing plates that work according to the mechanism of heat-induced latex-coalescence is their low sensitivity. It has been disclosed in the art that by decreasing the particle diameter of the hydrophobic thermoplastic particles in an imaging layer of a printing plate precursor, the sensitivity of the printing plate is substiantially increased. However, the shelf life of precursors comprising such small hydrophobic thermoplastic particles is highly recuced.

### SUMMARY OF THE INVENTION

It is an object of the present invention to provide a method for making a negative working, heat-sensitive lithographic printing plate precursor, that works according to the mechanism of heat-induced latex-coalescence that has a high sensitivity, excellent printing properties and a high shelf life.

This object is realized by claim 1, i.e. a method for making a lithographic printing plate precursor comprising the steps of
(i) providing a grained and anodized aluminum support;
(ii) treating the support with an aqueous solution comprising a salt of zirconium;
(iii) treating the support with an aqueous solution comprising a compound comprising a phosphonic acid group and/or an ester or a salt thereof;
(iv) applying a coating comprising hydrophobic particles and a binder;
(v) drying said coating.

According to the present invention, it was surprisingly found that the shelf life of a printing plate comprising a grained and anodized aluminum support which was first treated with an aqueous solution containing a salt of zirconium (solution 1) followed by an aqueous solution containing a compound comprising a phosphonic acid group and/or an ester or a salt thereof (solution 2), is substantially improved compared to such printing plates comprising supports post-treated according to the prior art. Moreover, it was found that not only the chemical composition of the applied solutions is important but also the order of their application—i.e. first post-treating with solution 1 followed by post-treatment with solution 2—is essential for obtaining the good shelf life results.

Other features, elements, steps, characteristics and advantages of the present invention will become more apparent from the following detailed description of preferred embodiments of the present invention.

### DETAILED DESCRIPTION OF THE INVENTION

The support of the lithographic printing plate precursor is a grained and anodized aluminum support. The support may be a sheet-like material such as a plate or it may be a cylindrical element such as a sleeve which can be slid around a print cylinder of a printing press. The aluminum support has usually a thickness of about 0.1-0.6 mm. However, this thickness can be changed appropriately depending on the size of the printing plate used and/or the size of the plate-setters on which the printing plate precursors are exposed.

The aluminum is preferably grained by electrochemical graining, and anodized by means of anodizing techniques employing phosphoric acid or a sulphuric acid/phosphoric acid mixture. Methods of both graining and anodization of aluminum are well known in the art and are for example disclosed in GB 2,088,901.

By graining (or roughening) the aluminum support, both the adhesion of the printing image and the wetting characteristics of the non-image areas are improved. By varying the type and/or concentration of the electrolyte and the applied voltage in the graining step, different type of grains can be obtained. The surface roughness is often expressed as arithmetical mean center-line roughness Ra (ISO 4287/1 or DIN 4762) and may vary between 0.05 and 1.5 μm. The aluminum substrate of the current invention has preferably an Ra value below 0.45 μm, more preferably below 0.40 μm, even more preferably below 0.30 μm and most preferably below 0.25 μm. The lower limit of the Ra value is preferably about 0.1 μm. More details concerning the preferred Ra values of the surface of the grained and anodized aluminum support are described in EP 1 356 926.

By anodising the aluminum support, its abrasion resistance and hydrophilic nature are improved. The microstructure as well as the thickness of the Al₂O₃ layer are determined by the anodising step, the anodic weight (g/m² Al₂O₃ formed on the aluminium surface) varies between 1 and 8 g/m². In the current invention, the anodic weight is preferably ≧3 g/m², more preferably ≧3.2 g/m²; most preferably ≧3.5 g/m². An anodic weight of ≧4.0 g/m² is also of particular interest in the current invention.

An optimal ratio between pore diameter of the surface of the aluminium support and the average particle size of hydrophobic thermoplastic particles which may be provided thereon may enhance the press life of the printing plate and may improve the toning behaviour of the prints. This ratio of the average pore diameter of the surface of the aluminium support to the average particle size of the thermoplastic particles which may be present in the image-recording layer of the coating, preferably ranges from 0.05:1 to 0.8:1, more preferably from 0.10:1 to 0.35:1.

The grained and anodized aluminum support is post-treated to improve the hydrophilic properties of its surface. In a first post-treatment step, the support is treated with an aqueous solution comprising a salt of zirconium. The salt of zirconium may include the metal either as the cation, for example in a halide, sulphate or nitrate salt, or as part of a complexed anion, for example in a fluorozirconate salt. The preferred salts are salts wherein the metal is present in a metal-complex anion. Examples of the first group of salts include zirconium phosphate, zirconium fluoride, zirconium chloroxide, zirconium dioxide, zirconium oxychloride, and zirconium tetrachloride. Examples of salts wherein the zirconium is present in a metal-complex anion include ammonium hexafluorozirconate, ammonium heptafluorozirconate, alkali metal fluorozirconates such as alkali metal hexafluorozirconates. The most preferred examples are the alkali metal fluorozirconates, particularly alkali metal hexafluorozirconate, more particularly potassium or sodium hexafluorozirconate (K₂ZrF₆ and Na₂ZrF₆).

The treatment with an aqueous solution containing a salt of zirconium is performed by for example dipping the support at a temperature of preferably 30-120° C., more preferably at a temperature of 50-100° C., and for preferably a time period of 0.5-80 s, more preferably for 2-50 s, most preferably for 2-10 s, in said aqueous solution having a concentration of preferably 0.5-50 g/l, more preferably a concentration of 0.5-15 g/l. After this treatment, the support is preferably dried at a temperature varying between room temperature (defined as 20° C.) and 200°, more preferably at a temperature between room temperature and 180° C.

Following the treatment of the support with an aqueous solution comprising a salt of zirconium; the support is further treated with an aqueous solution comprising a compound comprising a phosphonic acid group and/or an ester or a salt thereof.

Suitable examples of a compound with a phosphonic acid group are represented by the following formula I:

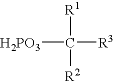

or a salt thereof and wherein:
R¹ and R² independently represent hydrogen, an optionally substituted straight, branched, cyclic or heterocyclic alkyl group having unto 8 carbon atoms, a halogen, a hydroxyl group, an optionally substituted aryl or heteroaryl group;
R³ represents an optionally substituted straight, branched, cyclic or heterocyclic alkyl group having unto 8 carbon atoms, a halogen, a hydroxyl group, an optionally substituted aryl or heteroaryl group, a carboxyl group, a phosphonic acid group, a phosphoric acid group, a sulphuric acid group or a sulphonic acid group.

The optional substituents present on the straight, branched, cyclic or heterocyclic alkyl group or on the aryl or heteroaryl group represent a halogen such as a chlorine or bromine atom, a hydroxyl group, an amino group, a (di)alkylamino group, an alkoxy group, a carboxyl group, a sulphonic acid group, a sulphuric acid group, phosphoric acid group and a phosphonic acid group. The aryl or heteroaryl group may further comprise an alkyl group as optional substituent.

In a more preferred embodiment, the compound with a phosphonic acid group is represented by formula II:

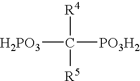

or a salt thereof and wherein:
R⁴ and R⁵ independently represent hydrogen, an optionally substituted straight, branched, cyclic or heterocyclic alkyl group having unto 8 carbon atoms, a halogen, a hydroxyl group, an optionally substituted aryl or heteroaryl group.

The optional substituents present on the straight, branched or cyclic or heterocyclic alkyl group or on the aryl or heteroaryl group represent a halogen such as a chlorine or bromine atom, a hydroxyl group, an amino group, a (di)alkylamino group, an alkoxy group, a carboxyl group, a sulphonic acid group, a sulphuric acid group, a phosphoric acid group and a phosphonic acid group. The aryl or heteroaryl group may further comprise an alkyl group as optional substituent.

In a most preferred embodiment, the compound with a phosphonic acid group is represented by formula III:

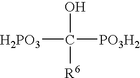

or a salt thereof and wherein:
R⁶ independently represent hydrogen, an optionally substituted straight, branched, cyclic or heterocyclic alkyl group or an optionally substituted aryl or heteroaryl group.

The optional substituents present on the straight, branched or cyclic or heterocyclic alkyl group or on the aryl or heteroaryl group represent a halogen such as a chlorine or bromine atom, a hydroxyl group, an amino group, a (di)alkylamino group, an alkoxy group, a carboxyl group, a sulphonic acid group, a sulphuric acid group, phosphoric acid group and a phosphonic acid group. The aryl or heteroaryl group may further comprise an alkyl group as optional substituent.

Specific compound especially suitable to be used in the current invention are the following compounds com-1 and cam-2:

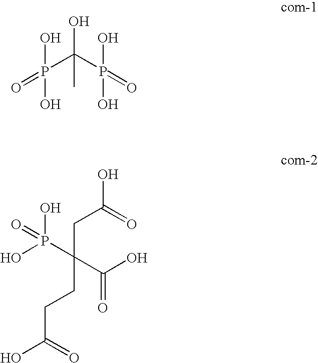

Preferably the compound with a phosphonic acid group and/or an ester or a salt thereof is a polymer comprising a repeating structural unit which comprises the phosphonic acid group and/or an ester or a salt thereof. Suitable examples of these polymers include polyvinylphosphonic acid, polyvinylmethylphosphonic acid, phosphonic acid esters of polyvinyl alcohol and a copolymer of acrylic acid and vinylphosphonic acid. Polyvinylphosphonic acid is highly preferred.

The preferred concentration of aqueous solution comprising a compound comprising a phosphonic acid group and/or an ester or a salt thereof ranges between 0.5-100 g/l, more preferably a concentration of 1-50 g/l. The dipping temperature is preferably 20-120° C., and more preferably 50-100° C. The dipping time is preferably 1-120 s, more preferably 2-60 s, most preferably 5-45 s. After this treatment, the support is preferably dried at a temperature varying between room temperature (defined as 20° C.) and 200°, more preferably at a temperature between room temperature and 180° C.

In a highly preferred embodiment, the support is first treated with a solution comprising an alkali metal salt of hexafluorozirconate followed by a treatment with a solution comprising polyvinylphosphonic acid.

Specifically, the solution for a post-anodic treatment may also contain materials such as sequestering agents, tannin, sulphuric acid, fluorides and other additives which are known to improve the lithographic properties of a substrate.

Various coating techniques may be employed for application of the post anodic solution, such as dip coating, spray coating, slot coating, reverse roll coating or electrochemical coating; most preferred, however, is dip and spray coating. Single pass processes are also preferred since they facilitate the avoidance of contamination which could otherwise occur as a consequence of re-circulation of the solution.

The lithographic printing plate precursor of the present invention comprises a heat-sensitive coating on the hydrophilic support. Said heat-sensitive coating comprises thermoplastic polymer particles which are preferably dispersed in a hydrophilic binder. The coating may comprise one or more layer(s) and the layer comprising the hydrophobic thermoplastic particles is referred to herein as the image-recording layer.

Due to heat generated during the exposure step, the thermoplastic polymer particles may fuse or coagulate so as to form a developer-resistant phase which corresponds to the printing areas of the printing plate. Coagulation may result from heat-induced coalescence, softening or melting of the thermoplastic polymer particles. The thermoplastic polymer particles preferably have an average particle size below 200 nm, preferably between 10 nm to 75 nm, more preferably between 15 nm and 65 nm and most preferably between 20 nm and 55 nm. The thermoplastic polymer particles have preferably an average particle size of less than 45 nm, more preferably of less than 38 nm and most preferably of less than 36 nm. The particle size is defined as the particle diameter, measured by Photon Correlation Spectrometry, also known as Quasi-Elastic or Dynamic Light-Scattering. The amount of hydrophobic thermoplastic polymer particles present in the image-recording layer of the coating is preferably at least 60% by weight, more preferably at least 70% by weight and most preferably at least 80% by weight. Alternatively, the amount of hydrophobic thermoplastic polymer particles in the image-recording layer of the coating is between 65% by weight and 85% by weight, and more preferably between 75% by weight and 85% by weight. The weight percentage of the thermoplastic polymer particles is determined relative to the weight of all the components in the image-recording layer.

The thermoplastic polymer particles are preferably hydrophobic polymers selected from polyethylene, poly(vinyl)chloride, polymethyl(meth)acrylate, polyethyl (meth)acrylate, poyvinylidene chloride, poly(meth)acrylonitrile, polyvinylcarbazole, polystyrene or copolymers thereof. According to a preferred embodiment, the thermoplastic polymer particles comprise polystyrene or derivatives thereof, mixtures comprising polystyrene and poly(meth)acrylonitrile or derivatives thereof, or copolymers comprising polystyrene and poly(meth)acrylonitrile or derivatives thereof. The latter copolymers may comprise at least 50% by weight of polystyrene, and more preferably at least 65% by weight of polystyrene. In order to obtain sufficient resistivity towards organic chemicals such as hydrocarbons used in plate cleaners, the thermoplastic polymer particles preferably comprise at least 5% by weight of nitrogen containing units as described in EP 1 219 416, more preferably at least 30% by weight of nitrogen containing units, such as (meth)acrylonitrile. According to the most preferred embodiment, the thermoplastic polymer particles consist essentially of styrene and acrylonitrile units in a weight ratio between 1:1 and 5:1 (styrene:acrylonitrile), e.g. in a 2:1 ratio.

The weight average molecular weight of the thermoplastic polymer particles may range from 5,000 to 1,000,000 g/mol.

The thermoplastic polymer particles present in the coating can be applied onto the lithographic base in the form of a dispersion in an aqueous coating liquid and may be prepared by the methods disclosed in U.S. Pat. No. 3,476,937 or EP 1 217 010. Another method especially suitable for preparing an aqueous dispersion of the thermoplastic polymer particles comprises:
dissolving the thermoplastic polymer in an organic water immiscible solvent,
dispersing the thus obtained solution in water or in an aqueous medium and
removing the organic solvent by evaporation.

The coating further comprises a hydrophilic binder which is preferably soluble in an aqueous developer. Examples of suitable hydrophilic binders are homopolymers and copolymers of vinyl alcohol, acrylamide, methylol acrylamide, methylol methacrylamide, acrylic acid, methacrylic acid, hydroxyethyl acrylate, hydroxyethyl methacrylate and maleic anhydride/vinylmethylether copolymers.

The coating preferably also contains one or more compound(s) which absorbs infrared light and convert the absorbed energy into heat. The amount of infrared absorbing agent(s) in the coating is preferably between 0.25 and 25.0% by weight, more preferably between 0.5 and 20.0% by weight. The infrared absorbing compound(s) can be present in the image-recording layer and/or an optional other layer. Preferred IR absorbing compounds are dyes such as cyanine, merocyanine, indoaniline, oxonol, pyrilium and squarilium dyes or pigments such as carbon black. Examples of suitable infrared absorbers are described in e.g. EP 823 327, EP 978 376, EP 1 029 667, EP 1 053 868, EP 1 093 934; WO 97/39894 and WO 00/29214. Infrared absorbing dyes which become intensively colored after exposure by infrared irradiation or heating and thereby form a visible image, are also of interest and are extensively described in EP 1 614 541 and PCT 2006/063327. Another preferred IR compound is the following cyanine dye IR-1:

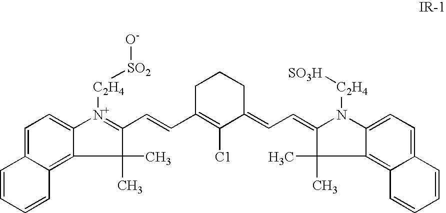

The coating may in addition to the image-recording layer also contain one or more additional layer(s). Besides the optional light-absorbing layer comprising one or more compounds that are capable of converting infrared light into heat, the coating may also comprise a protective layer such as a covering layer which is removed during processing. This layer protects the surface of the coating in particular from mechanical damage and generally comprises at least one water-soluble binder, such as polyvinyl alcohol, polyvinylpyrrolidone, partially hydrolyzed polyvinyl acetates, gelatin, carbohydrates or hydroxyethylcellulose. The protective layer can be produced in any known manner such as from an aqueous solution or dispersion and may contain small amounts, i.e. less than 5% by weight, of organic solvents. The thickness of the protective layer is advantageously up to 5.0 μm thick, preferably from 0.1 to 3.0 μm, particularly preferably from 0.15 to 1.0 μm. The coating may further comprise for example an adhesion-improving layer between the image-recording layer and the support.

Optionally, the coating may further contain additional ingredients such as surfactants, especially perfluoro surfactants, colorants, silicon or titanium dioxide particles or polymers particles such as matting agents and spacers. Especially addition of colorants such as dyes or pigments which provide a visible color to the coating and remain in the exposed areas of the coating after the processing step, are advantageous. Thus, the image-areas which are not removed during the processing step form a visible image on the printing plate and examination of the developed printing plate already at this stage becomes feasible. Typical examples of such contrast dyes are the amino-substituted tri- or diarylmethane dyes, e.g. crystal violet, methyl violet, victoria pure blue, flexoblau 630, basonylblau 640, auramine and malachite green. Also the dyes which are discussed in depth in the detailed description of EP 400 706 are suitable contrast dyes. Dyes which, combined with specific additives, only slightly color the coating but which become intensively colored after exposure, are also of interest.

Preferably the image-recording layer comprises an organic compound, characterised in that said organic compound comprises at least one phosphonic acid group or at least one phosphoric acid group or a salt thereof, as described in the unpublished European Patent Application 05 109 781 (filed 2005-Oct.-20). In a particularly preferred embodiment the image-recording layer comprises an organic compound as represented by formula III above. These compounds may be present in the image-recording layer in an amount between 0.05 and 15% by weight, preferably between 0.5 and 10% by weight, more preferably between 1 and 5% by weight relative to the total weight of the ingredients of the image-recording layer.

Any coating method can be used for applying two or more coating solutions to the hydrophilic surface of the support. The multi-layer coating can be applied by coating/drying each layer consecutively or by the simultaneous coating of several coating solutions at once. In the drying step, the volatile solvents are removed from the coating until the coating is self-supporting and dry to the touch. However it is not necessary (and may not even be possible) to remove all the solvent in the drying step. Indeed the residual solvent content may be regarded as an additional composition variable by means of which the composition may be optimized. Drying is typically carried out by blowing hot air onto the coating, typically at a temperature of at least 70° C., suitably 80-150° C. and especially 90-140° C. Also infrared lamps can be used. The drying time may typically be 15-600 seconds.

Between coating and drying, or after the drying step, a heat treatment and subsequent cooling may provide additional benefits, as described in WO99/21715, EP-A 1074386, EP-A 1074889, WO00/29214, and WO/04030923, WO/04030924, WO/04030925.

The printing plate precursor of the present invention can be image-wise exposed directly with heat, e.g. by means of a thermal head, or indirectly by infrared light by means of e.g. LEDs or an infrared laser. The infrared light is preferably converted into heat by an IR light absorbing compound as discussed above. Preferably lasers, emitting near infrared light having a wavelength in the range from about 700 to about 1500 nm, e.g. a semiconductor laser diode, a Nd:YAG or a Nd:YLF laser, are used. Most preferably, a laser emitting in the range between 780 and 830 nm is used. The required laser power depends on the sensitivity of the image-recording layer, the pixel dwell time of the laser beam, which is determined by the spot diameter (typical value of modern plate-setters at 1/e² of maximum intensity: 10-25 μm), the scan speed and the resolution of the exposure apparatus (i.e. the number of addressable pixels per unit of linear distance, often expressed in dots per inch or dpi; typical value: 1000-4000 dpi).

Two types of laser-exposure apparatuses are commonly used: internal (ITD) and external drum (XTD) platesetters. ITD plate-setters for thermal plates are typically characterized by a very high scan speed up to 500 m/sec and may require a laser power of several Watts. XTD plate-setters for thermal plates having a typical laser power from about 200 mW to about 1 W operate at a lower scan speed, e.g. from 0.1 to 10 m/sec. An XTD platesetter equipped with one or more laserdiodes emitting in the wavelength range between 750 and 850 nm is an especially preferred embodiment for the method of the present invention.

The known plate-setters can be used as an off-press exposure apparatus, which offers the benefit of reduced press down-time. XTD plate-setter configurations can also be used for on-press exposure, offering the benefit of immediate registration in a multi-color press. More technical details of on-press exposure apparatuses are described in e.g. U.S. Pat. No. 5,174,205 and U.S. Pat. No. 5,163,368.

After exposure, the precursor can be developed by means of a suitable processing liquid, such as an aqueous alkaline solution, whereby the non-image areas of the coating are removed; the development step may be combined with mechanical rubbing, e.g. by using a rotating brush. During development, any water-soluble protective layer present is also removed.

A preferred aqueous alkaline developer is a silicate-based developer which has a ratio of silicon dioxide to alkali metal oxide of at least 1 and with a pH ≧11. Preferred alkali metal oxides include Na₂O and K₂O, and mixtures thereof. A particularly preferred silicate-based developer solution is a developer solution comprising sodium or potassium metasilicate, i.e. a silicate where the ratio of silicon dioxide to alkali metal oxide is 1. The developer may optionally contain further components, such as buffer substances, complexing agents, antifoaming agents, organic solvents in small amounts, corrosion inhibitors, dyes, surfactants and/or hydrotropic agents as known in the art. Preferred surfactants include non-ionic surfactants such as Genapol C 200 (trademark from Clariant GmbH) and amphoteric surfactants such as librateric AA30 (trademark from Libra Chemicals Limited).

The development is preferably carried out at temperatures of from 20 to 40° C. in automated processing units as customary in the art. In the embodiment where a silicate-based developer is used, for regeneration, alkali metal silicate solutions having alkali metal contents of from 0.6 to 2.0 mol/l can suitably be used. These solutions may have the same silica/alkali metal oxide ratio as the developer (generally, however, it is lower) and likewise optionally contain further additives. The required amounts of regenerated material must be tailored to the developing apparatuses used, daily plate throughputs, image areas, etc. and are in general from 1 to 50 ml per square meter of plate precursor. The addition of replenisher can be regulated, for example, by measuring the conductivity of the developer as described in EP 556 690.

The printing plate can also be developed using plain water or aqueous solutions, e.g. a gumming solution. The gum solution is typically an aqueous liquid which comprises one or more surface protective compounds that are capable of protecting the lithographic image of a printing plate against contamination or damaging. Suitable examples of such compounds are film-forming hydrophilic polymers or surfactants. The gum solution has preferably a pH from 4 to 10, more preferably from 5 to 8. Preferred gum solutions are described in EP 1 342 568.

Alternatively, the printing plate precursor can after exposure directly be mounted on a printing press and be developed on-press by supplying ink and/or fountain to the precursor.

More details concerning the development step can be found in for example EP 1 614 538, EP 1 614 539, EP 1 614 540 and WO/2004071767.

The development step may be followed by a rinsing step and/or a gumming step. The gumming step involves post-treatment of the lithographic printing plate with a gum solution as described above.

The plate precursor may additionally be treated with a suitable correcting agent or preservative as known in the art. To increase the resistance of the finished printing plate and hence to extend the run length, the layer can be heated to elevated temperatures (so called “baking”). During the baking step, the plate can be heated at a temperature which is higher than the glass transition temperature of the thermoplastic particles, e.g. between 100° C. and 230° C. for a period of 40 minutes to 5 minutes. A preferred baking temperature is above 60° C. For example, the exposed and developed plates can be baked at a temperature of 230° C. for 5 minutes, at a temperature of 150° C. for 10 minutes or at a temperature of 120° C. for 30 minutes. Baking can be done in conventional hot air ovens or by irradiation with lamps emitting in the infrared or ultraviolet spectrum. As a result of this baking step, the resistance of the printing plate to plate cleaners, correction agents and UV-curable printing inks increases. Such a thermal post-treatment is for example described in DE 1 447 963 and GB 1 154 749.

The printing plates thus obtained can be used for conventional, so-called wet offset printing, in which ink and an aqueous dampening liquid are supplied to the plate. Another suitable printing method uses so-called single-fluid ink without a dampening liquid. Suitable single-fluid inks have been described in U.S. Pat. No. 4,045,232; U.S. Pat. No. 4,981,517 and U.S. Pat. No. 6,140,392. In a most preferred embodiment, the single-fluid ink comprises an ink phase, also called the hydrophobic or oleophilic phase, and a polyol phase as described in WO 00/32705.

### EXAMPLES

### Example 1

### 1. Preparation of the Reference Substrate AS-01

A 0.3 mm thick aluminium foil was degreased by spraying with an aqueous solution containing 34 g/l NaOH at 70° C. for 6 seconds and rinsed with demineralised water for 3.6 seconds. The foil was then electrochemically grained during 8 seconds using an alternating current in an aqueous solution containing 15 g/l HCl, 15 g/l SO4²⁻ ions and 5 g/l Al³⁺ ions at a temperature of 37° C. and a current density of about 100 A/dm² and charge density of about 800 C/dm². Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 33 A/dm² (charge density of 330 C/dm²), then washed with demineralised water for 7 seconds and post-treated for 4 seconds by spraying with a solution containing 2.2 g/l PVPA at 70° C., rinsed with demineralised water for 3.5 seconds and dried at 120° C. for 7 seconds (Table 1). The support thus obtained is characterised by a surface roughness Ra of 0.35-0.4 μm (measured with interferometer NT1100) and has an anodic weight of about 4.0 g/m2.

### 2. Preparation of the Post-Anodic Treated (PAT) Substrates AS-02 to AS-39

A 0.3 mm thick aluminium foil was degreased by spraying with an aqueous solution containing 34 g/l NaOH at 70° C. for 6 seconds and rinsed with demineralised water for 3.6 seconds. The foil was then electrochemically grained during 8 seconds using an alternating current in an aqueous solution containing 15 g/l HCl, 15 g/l SO4²⁻ ions and 5 g/l Al³⁺ ions at a temperature of 37° C. and a current density of about 100 A/dm² (charge density of about 800 C/dm²). Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 33 A/dm² (charge density of 330 C/dm²), then washed with demineralised water for 7 seconds and dried at 120° C. for 7 seconds. The untreated substrate AS-02 was obtained.

The support thus obtained has a surface roughness Ra of 0.35-0.4 μm (measured with interferometer NT1100) and an anodic weight of 4.0 g/m².

Subsequently, the untreated substrate AS-02 was dipped in a ZAT solution and/or a PVPA solution (see below) according to the conditions described in Table 1 (comparative examples AS-03 to AS-16) and Table 2 (inventive examples AS-17 to AS-39). The temperature of the solutions in Table 1 (PAT Sol 1 and PAT Sol 2) was 80° C., except for AS-01, AS-03 and AS-04 where a temperature of 70° C. was used. The dipping temperature and dipping time utilized for the first PAT solutions in Table 2 (PAT sol 1) were respectively 80° C. and 5 s. After each dipping step, the post-anodic treated samples were rinsed for 5 seconds with demineralized water and dried according to the conditions described in Tables 1 and 2.

### ZAT Solution:

K₂ZrF₆ (commercially available from Atochem SA) was dissolved in demineralized water in concentrations of 1, 4 or 10 g/liter. These solutions are called herein “ZAT solutions”.

### PVPA Solution:

Solutions of PVPS100 (polyvinylphosphonic acid, trademark of Clariant GmbH) in demineralized water at concentrations of 2.2, 10 or 20 g/liter were used. These solutions are called herein “PVPA solutions”.

### Mixed ZAT/PVPA Solution:

Also mixed solutions of K₂ZrF₆ and Polyvinylphosphonic acid were made at concentrations of respectively 1 g/l and 2.2 g/l in demineralized water.

TABLE 1
Comparative Examples.

| | | | | Drying | | | | | Drying | Drying |
|---|---|---|---|---|---|---|---|---|---|---|
| Aluminium | | Conc. | Dipping | temp. | Drying | PAT | Conc | Dipping | temp. | time |
| Substrate | PAT Sol 1 | g/l | time S | ° C.* | time S | Sol 2 | g/l | time s | ° C. | s |
| AS-O1 | PVPA | 2.2 | Spray | 120 | 7 | — | | — | — | — |
| AS-02 | — | — | — | — | — | — | — | — | — | — |
| AS-03 | PVPA | 2.2 | 5 | RT | Till dry | — | — | — | — | — |
| AS-04 | PVPA | 10 | 5 | RT | Till dry | — | — | — | — | — |
| AS-05 | PVPA | 20 | 30 | RT | Till dry | — | — | — | — | — |
| AS-06 | ZAT | 1 | 5 | RT | Till dry | — | — | — | — | — |
| AS-07 | ZAT | 4 | 5 | RT | Till dry | — | — | — | — | — |
| AS-08 | ZAT | 10 | 5 | RT | Till dry | — | — | — | — | — |
| AS-09 | PVPA | 20 | 30 | 120 | 180 | — | — | — | — | — |
| AS-10 | PVPA | 20 | 30 | 160 | 180 | — | — | — | — | — |
| AS-11 | ZAT | 4 | 5 | 120 | 180 | — | — | — | — | — |
| AS-12 | ZAT | 4 | 5 | 160 | 180 | — | — | — | — | — |
| AS-13 | PVPA | 20 | 30 | 120 | 180 | ZAT | 4 | 5 | 120 | 180 |
| AS-14 | PVPA | 20 | 30 | 160 | 180 | ZAT | 4 | 5 | 160 | 180 |
| AS-15 | ZAT + | 1 + 2.2 | 5 | RT | Till dry | — | — | — | — | — |
| | PVPA | | | | | | | | | |
| AS-16 | ZAT + | 1 + 2.2 | 5 | 120 | 188 | — | — | — | — | — |
| | PVPA | | | | | | | | | |

*RT: room temperature

TABLE 2
inventive examples.

| Aluminium | PAT | Conc. | Drying | Drying | PAT | Conc. | Dipping | Dipping | Drying | Drying |
|---|---|---|---|---|---|---|---|---|---|---|
| Substrate | Sol. 1 | g/l | temp. ° C.* | time S | Sol. 2 | g/l | temp. ° C. | time s | temp.* ° C. | time s |
| AS-17 | ZAT | 1 | RT | Till dry | PVPA | 2.2 | 70 | 5 | RT | Till dry |
| AS-18 | ZAT | 4 | RT | Till dry | PVPA | 2.2 | 70 | 5 | RT | Till dry |
| AS-19 | ZAT | 10 | RT | Till dry | PVPA | 2.2 | 70 | 5 | RT | Till dry |
| AS-20 | ZAT | 1 | RT | Till dry | PVPA | 10 | 70 | 5 | RT | Till dry |
| AS-21 | ZAT | 4 | RT | Till dry | PVPA | 10 | 70 | 5 | RT | Till dry |
| AS-22 | ZAT | 10 | RT | Till dry | PVPA | 10 | 70 | 5 | RT | Till dry |
| AS-23 | ZAT | 1 | RT | Till dry | PVPA | 20 | 80 | 30 | RT | Till dry |
| AS-24 | ZAT | 4 | RT | Till dry | PVPA | 20 | 80 | 30 | RT | Till dry |
| AS-25 | ZAT | 10 | RT | Till dry | PVPA | 20 | 80 | 30 | RT | Till dry |
| AS-26 | ZAT | 4 | 120 | 180 | PVPA | 20 | 80 | 30 | 120 | 180 |
| AS-27 | ZAT | 4 | 160 | 180 | PVPA | 20 | 80 | 30 | 160 | 180 |
| AS-28 | ZAT | 4 | — | — | PVPA | 2.2 | 80 | 5 | 120 | 180 |
| AS-29 | ZAT | 4 | RT | Till dry | PVPA | 2.2 | 80 | 5 | 120 | 180 |
| AS-30 | ZAT | 4 | 120 | 180 | PVPA | 2.2 | 80 | 5 | RT | Till dry |
| AS-31 | ZAT | 4 | 120 | 180 | PVPA | 2.2 | 80 | 5 | 120 | 180 |
| AS-32 | ZAT | 4 | — | — | PVPA | 2.2 | 80 | 5 | 120 | 180 |
| AS-33 | ZAT | 4 | RT | Till dry | PVPA | 20 | 80 | 5 | 120 | 180 |
| AS-34 | ZAT | 4 | 120 | 180 | PVPA | 20 | 80 | 5 | RT | Till dry |
| AS-35 | ZAT | 4 | 120 | 180 | PVPA | 20 | 80 | 5 | 120 | 180 |
| AS-36 | ZAT | 1 | — | — | PVPA | 20 | 80 | 5 | 120 | 180 |
| AS-37 | ZAT | 1 | RT | Till dry | PVPA | 20 | 80 | 5 | 120 | 180 |
| AS-38 | ZAT | 1 | 120 | 180 | PVPA | 20 | 80 | 5 | RT | Till dry |
| AS-39 | ZAT | 1 | 120 | 180 | PVPA | 20 | 80 | 5 | 120 | 180 |

*RT: room temperature

### 3. Preparation of the Latex Lx-01

The polymer emulsion is prepared by means of a semi-continuous emulsion polymerisation were all monomers (styrene and acrylonitrile) are added to the reactor. All surfactant (3% towards the monomer amount) is present in the reactor before the monomer addition is started. In a double-jacketed reactor of 2 liter 10.8 grams of Sodium dodecyl sulfate (SDS Ultra Pure obtained via Alkemi B V, Lokeren, Belgium) and 1243.9 grams of demineralised water was added. The reactor was flushed with nitrogen and heated until 80 C. When the reactor content reached a temperature of 80 C, 12 gram of a 5% solution of sodium persulfate in water was added. The reactor is subsequently heated for 15 minutes at 80 C. Then the monomer mixture (238.5 gram of styrene and 121.5 grams of acrylonitrile) was dosed during 180 minutes. Simultaneously during the monomer addition an additional an aqueous persulfate solution was added (24 grams of a 5% aqueous Na₂S₂O₈ solution). After the monomer addition is finished the reactor is heated for 30 minutes at 80° C. To reduce the amount of residual monomer a redox-initiation system is added (1.55 gram sodium formaldehyde sulfoxylate dihydrate (SFS) dissolved in 120 gram water and 2.57 gram of a 70 wt % tert.butyl hydroperoxide (TBHP) diluted with 22.5 gram of water. The aqueous solutions of SFS and TBHP are added separately during 80 minutes. The reaction is then heated for another 10 minutes and is subsequently cooled to room temperature. 100 ppm of Proxyl ultra (5-bromo-5-nitro-1,3-dioaxane) is added as biocide and the latex is filtered using coarse filter paper.

This resulted in a latex dispersion with a solid content of 20.84% and a pH of 3.46. The average particle size was 36 nm (measured using a Brookhaven BI-90 analyzer, commercially available from Brookhaven Instrument Company, Holtsville, N.Y., USA.).

### 4. Preparation of the Printing Plate Precursors PPP-01 to PPP-39

The coating solution for the printing plate precursors PPP-01 to PPP-39 was prepared as follows: the latex dispersion LX-01 was added to demineralized water and the obtained dispersion was stirred for 10 minutes. Subsequently the IR-dye was added and after stirring the solution for 60 minutes, the polyacrylic acid solution was added. After 10 minutes of stirring the HEDP solution was added and subsequently after another 10 minutes of stirring the surfactant solution. The coating dispersion was stirred for another 30 minutes and the pH was adjusted to a value of 3.6. Table 3 lists the dry coating weight of the different ingredients of the coating.

TABLE 3
Dry coating weight.

| Ingredients | g/m² |
|---|---|
| Latex LX-01 (1) | 0.540 |
| IR-dye (2) | 0.108 |
| Polyacrylic acid (3) | 0.081 |
| HEDP (4) | 0.025 |
| Surfactant (5) | 0.005 |
| Total (g/m2) | 0.759 |

(1) latex LX-01 synthesized as in point 3 above;
(2)Aqueous IR dye solution containing 1% by weight of the following IR-dye : 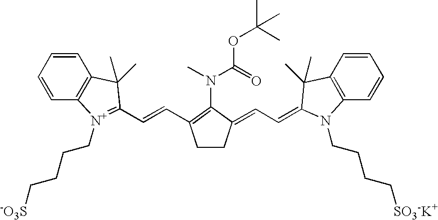
(3) Aqueous solution containing 5% by weight of polyacrylic acid (PAA) (Aquatreat AR7H commercially available from National Starch & Chemical Company);
(4) Aqueous solution containing 10% by weight hydroxyethyldiphosphonate (HEDP, commercially available from Solutia);
(5) Aqueous surfactant solution containing 5% by weight of the fluoro surfactant Zonyl FS0100 (trademark of Dupont).

The obtained coating solution was subsequently coated on the Al-substrates AS-01 to AS-39 with a coating knife at a wet thickness of 30 μm. After drying at 60° C. this resulted in printing plate precursors PPP-01 to PPP-39.

### 5. Exposure and Printing of the Printing Plate Precursors PPP-01 to PPP-39

Of each of printing plate precursors PPP-01 to PPP-39 one plate was immediately exposed (“fresh” printing plate precursors) and another plate was stored for 7 days at 80% relative humidity and 35° C. temperature before exposure; these are “aged” printing plate precursors.

All “fresh” and “aged” printing plate precursors were exposed on a Creo TrendSetter 3244 40W fast head IR-laser platesetter with an exposure series 210-180-150-120-90 mJ/cm² @ 150 rpm, using a addressability of 2400 dpi and a 200 lpi screen. The exposed printing plate precursors were directly mounted on a GTO46 printing press (available from Heidelberger Druckmaschinen AG) without any processing or pre-treatment. A compressible blanket was used and printing was done with 3% Agfa Prima FS101 (trademark of Agfa)+100 isopropanol as a fountain solution and K+E 800 black ink (trademark of K&E).

The following start-up procedure was used: first 5 revolutions with the dampening rollers engaged, then 5 revolutions with both the dampening and ink rollers engaged, then start printing. 1000 Prints were made on 80 g offset paper.

### 6. Printing Results

### 6.1 Sensitivity.

The plate sensitivity is defined as the lowest energy density at which the 2% dot is perfectly visible on print 1.000 by means of a 5× magnifying glass. The plate sensitivity obtained for all the fresh plates was ≦150 mJ/m², except for the comparative printing plates PP-02, PP-15 and PP-16 were the plate sensitivity was difficult to determine and was ≧200 mJ/m².

### 6.2 Shelf Life Results.

The shelf life of the printing plates was measured in terms of clean out results obtained on aged printing plates. A plate has a good shelf life if its clean-out behaviour is maintained or only slightly reduced after the aging period.

The clean-out results obtained for the fresh printing plates were excellent (=5) except for the fresh comparative printing plates PP-02 (no PAT treatment) and PP-15 and PP-16 (mixed single treatment PAT treatment) which did not clean out (clean out=0); a black print was obtained.

The clean-out results obtained for the aged comparative printing plates PP-01 to PP-16 and the aged inventive printing plates PP-017 to PP-39 are given in Table 4.

TABLE 4
Clean-out results of the aged printing plates.

| Comparative Printing | Clean- | Inventive Printing | |
|---|---|---|---|
| Plates* | out*** | Plates** | Clean-out*** |
| PP-01 (ref. ex.) | 1 | PP-17 | 4/5 |
| PP-02 | 0 | PP-18 | 4/5 |
| PP-03 | 1 | PP-19 | 4 |
| PP-04 | 2 | PP-20 | 4/5 |
| PP-05 | 2 | PP-21 | 4/5 |
| PP-06 | 2/3 | PP-22 | 4/5 |
| PP-07 | 2/3 | PP-23 | 4/5 |
| PP-08 | 2/3 | PP-24 | 5 |
| PP-09 | 2/3 | PP-25 | 4/5 |
| PP-10 | 2/3 | PP-26 | 4/5 |
| PP-11 | 2/3 | PP-27 | 4/5 |
| PP-12 | 2/3 | PP-28 | 4/5 |
| PP-13 | 3 | PP-29 | 4/5 |
| PP-14 | 3 | PP-30 | 4/5 |
| PP-15 | 0 | PP-31 | 4/5 |
| PP-16 | 0 | PP-32 | 5 |
| | | PP-33 | 5 |
| | | PP-34 | 5 |
| | | PP-35 | 5 |
| | | PP-36 | 4/5 |
| | | PP-37 | 4/5 |
| | | PP-38 | 4/5 |
| | | PP-39 | 4/5 |

*supports treated with a single PAT treatment, except for the support of PP-02 which was not post-treated;
**supports treated with a ZAT solution followed by a PVPA solution;
***The following clean-out criteria were used:
0 = black image at print ≦25 and print 250
1 = Severely toned image at print ≦25 but black print at print 250
2 = Severely toned image at print ≦25 and print 250
3 = Medium toned image at print ≦25 and print 250
4 = clean background at print ≦25 but slight toning at print 250
5 = clean background throughout the complete print run and wherein a value lower than 4 is not acceptable for high-quality printing.

The results in Table 4 show that:
printing plates having a support which was not post-anodic treated or had a single-step post-anodic treatment (either a ZAT, a PVPA solution or a mixed ZAT/PVPA solution: comparative printing plates PP-01 to PP-12, PP-15 and PP-16) give bad clean-out results after storage under warm and humid conditions;
supports which are first treated with a PVPA solution followed by a ZAT solution (PP-13 and PP-14) give an unacceptable clean-out result after storage;
printing plates having a support which was after anodization first treated with a ZAT solution and then with a PVPA solution—with or without intermediary drying between these 2 consecutive steps—give a good clean-out performance after storage under warm and humid conditions (inventive printing plates PP-17-PP-39).

These results show that the shelf life-measured in terms of clean-out behaviour—is significantly better for supports which were post-anodic treated with first a ZAT-solution followed by a PVPA solution.

### Example 2

### 1. Preparation of the Substrate AS-40

The reference substrate AS-01 and the comparative substrate AS-02 were prepared according to Example 1.

The untreated substrate AS-02 was first dipped for 5 s in a ZAT solution (4 g/l; see Example 1) at 80° C.; then the substrate was rinsed for 5 seconds with demineralized water followed by dipping the substrate in a PVPA solution (20 g/l; see Example 1) at 70° C. for 5 s and then dried for 5 min at 120° C. Substrate AS-40 is obtained.

### 2. Synthesis of the Latex LX-02

The polymer emulsion is prepared by means of a semi-continuous emulsion polymerization were all monomers (styrene and acrylonitrile) are added to the reactor. All surfactant (2.15% towards the monomer amount) is present in the reactor before the monomer addition is started. In a double-jacketed reactor of 400 liter, 17.2 kg of an 10 wt % aqueous solution of Sodium dodecyl sulfate (Texapon K12 obtained via Cognis) and 265 kg of dematerialized water was added. The reactor was brought under inert atmosphere by 3 times vacuum/nitrogen exchange. The reactor content is stirred at 100 rpm and heated until 82° C. When the reactor content reached a temperature of 82° C., 6.67 kg of a 2% of sodium persulfate in water was added. The reactor is subsequently heated for 15 minutes at 82° C. Then the monomer mixture (53.04 kg of styrene and 27.0 of acrylonitrile) was dosed during 3 hours. Simultaneously during the monomer addition an aqueous persulfate solution was added (13.34 kg of a 2% aqueous Na2S2O8 solution) during 3 hours. The monomer flask is flushed with 5 liter of dematerialized water. After the monomer addition is finished the reactor is heated for 60 minutes at 82° C. To reduce the amount of residual monomer a redox-initiation system is added (340 gram of sodium formaldehyde sulfoxylate dihydrate (SFS) dissolved in 22.81 kg water and 570 gram of a 70 wt % tert.butyl hydroperoxide (TBHP) diluted with 4.8 kg of water. The aqueous solutions of SFS and TBHP are added separately during 2 hours and 20 minutes. The reaction is then heated for another 10 minutes at 82° C. and is subsequently cooled to room temperature. 800 Grams of a 5 wt % Proxyl ultra aqueous solution is added as biocide (100 ppm) and the latex is filtered using a 5 micron filter.

The prepared latex has a solid content of 19.92%, a pH of 3.2 and a particle size of 45 nm (measured using a Brookhaven BI-90 analyzer, commercially available from Brookhaven Instrument Company, Holtsville, N.Y., USA).

### 3. Preparation of the Printing Plate Precursors PPP-40 to PPP-45

The coating solution for the printing plate precursors PPP-40 to PPP-45 was prepared as follows: the latex dispersion LX-01 (see Example 1) or LX-02 was added to demineralized water and the obtained dispersion was stirred for 10 minutes. Subsequently the IR-dye was added and after stirring the solution for 60 minutes, the polyacrylic acid solution was added. After 10 minutes of stirring the HEDP solution was added and subsequently after another 10 minutes of stirring the contrast dyes, pigment dispersions and/or surfactant solution were added. The coating dispersion was stirred for another 30 minutes and the pH was adjusted to a value of 3.6. Three different coating solution were prepared and Table 5 lists the dry coating weight of the different ingredients.

The coating solutions were subsequently coated on the Al-substrate AS-02 (comparative) and AS-40 with a coating knife at a wet thickness of 30 μm. After drying at 60° C. this resulted in printing plate precursors PPP-40 to PPP-45.

TABLE 5
Dry coating weight.

| | Coating 1 | Coating | Coating 3 |
|---|---|---|---|
| Ingredients | g/m² | g/m² | g/m² |
| Latex LX-01 (1) | 0.480 | 0.512 | |
| Latex LX-02 (2) | | | 0.485 |
| IR-dye 2 (3) | 0.096 | | |
| IR-dye 3 (4) | | 0.075 | 0.044 |
| Contrast dye CD-1 (5) | | | 0.035 |
| Contrast dye CD-2 (5) | | | 0.022 |
| Blue pigment (6) | | 0.013 | |
| Violet pigment (7) | | 0.039 | |
| Polyacrylic acid (8) | 0.054 | 0.057 | 0.063 |
| HEDP (9) | 0.024 | 0.024 | 0.027 |
| Surfactant (10) | 0.005 | 0.005 | 0.008 |
| Total (g/m2) | 0.716 | 0.725 | 0.684 |

(1) latex LX-01 as synthesized in Example 1;
(2) latex LX-02 as synthesized above;
(3) IR dye 2: 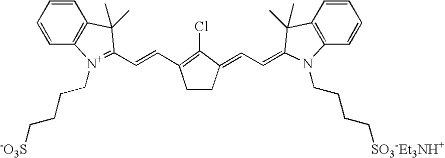
(4) IR dye 3: Aqueous solution containing 1% by weight of the following dye: 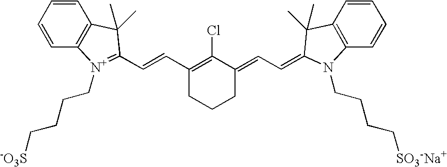
(5) Aqueous solution (MeOH/Water 50/50) containing 1% by weight of the contrast dyes CD-1 (blue) or CD-2 (magenta): 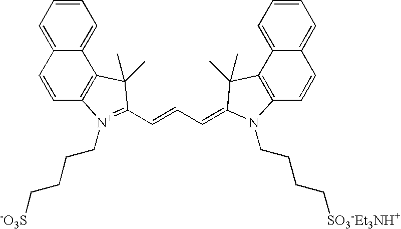 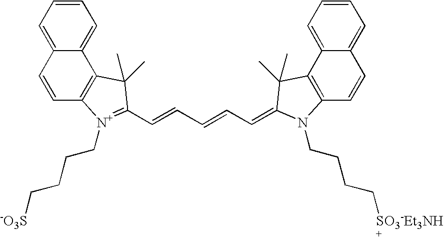
(6) 20% by weight aqueous dispersion of the pthalocyanine dye Heliogen Blau D7490, trademark of BASF (blue pigment).
(7) 20% by weight aqueous dispersion of PV Fast Violet RL trademark of Clariant (violet pigment);
(8) Aqueous solution containing 5% by weight of polyacrylic acid (PAA) (commercially available from Aquatreat AR7H from National Starch & Chemical Company);
(9) Aqueous solution containing 10% by weight hydroxyethyldiphosphonate (HEDP, commercially available from Solutia);
(10) Aqueous surfactant solution containing 5% by weight of the fluoro surfactant Zonyl FS0100 (trademark of Dupont).

### 4. Exposure, processing and printing of the printing plate precursors PPP-40 to PPP-45

Of each of printing plate precursors PPP-40 to PPP-45 one precursor was immediately exposed (“fresh” printing plate precursors) and another precursor was stored for 7 days at 80% relative humidity and 35° C. temperature before exposure; these are “aged” printing plate precursors.

All “fresh” and “aged” printing plate precursors were exposed on a Creo TrendSetter 3244 40W fast head IR-laser platesetter with an exposure series 210-180-150-120-90 mJ/cm² @ 150 rpm, using a addressability of 2400 dpi and a 200 lpi screen.

The exposed printing plate precursors were subsequently processed in an Agfa COU85 (trademark of Agfa, clean-out unit) operating at a speed of 1.1 m/min, using Agfa RC520 (trademark of Agfa) at 22° C. as a gumming solution.

The printing plates were then mounted on a GTO46 printing press (available from Heidelberger Druckmaschinen AG). A compressible blanket was used and printing was done with 3% Agfa Prima FS101 (trademark of Agfa)+10% isopropanol as a fountain solution and K+E 800 black ink (trademark of K&E).

The following start-up procedure was used: first 5 revolutions with the dampening rollers engaged, then 5 revolutions with both the dampening and ink rollers engaged, then start printing. 250 prints were made on 80 g offset paper.

### 5. Printing Results

### 5.1 Sensitivity

The plate sensitivity is defined as the lowest energy density at which the 2% dot is perfectly visible on print 1.000 by means of a 5× magnifying glass (Table 6).

### 5.2 Shelf Life Results.

The shelf life of the printing plates was measured in terms of clean out results obtained on aged printing plates. A plate has a good shelf life if its clean-out behaviour is maintained or only slightly reduced after the aging period.

The clean-out results obtained for the fresh comparative and inventive printing plates PP-40 to PP-45, was for all plates equal to 5. The clean-out results measured on the aged samples is given in Table 6.

TABLE 6
Clean-out results of the aged printing plates.

| | Al. | | Sensitivity | Clean- |
|---|---|---|---|---|
| Printing Plate | Substr. | Coating | mJ/cm2 | out* |
| PP-40 | AS-O1 | 1 | 180 mJ/cm² | 3 |
| (comparative ex.) | | | | |
| PP-41 | AS-01 | 2 | 180 mJ/cm² | 2 |
| (comparative ex.) | | | | |
| PP-42 | AS-01 | 3 | 210 mJ/cm² | 3 |
| (comparative ex.) | | | | |
| PP-43 | AS-40 | 1 | 180 mJ/cm² | 5 |
| (inventive ex.) | | | | |
| PP-44 | AS-40 | 2 | 180 mJ/cm² | 5 |
| (inventive ex.) | | | | |
| PP-45 | AS-40 | 3 | 210 mJ/cm² | 5 |
| (inventive ex.) | | | | |

*The following clean-out criteria were used:
0 = completely black image throughout the whole print run;
1 = medium toned image at print 1 and completely black from print >5 to print 250;
2 = medium toned image at print <5 and completely black print from print >15 to print 250;
3 = medium toned image at print <10 and completely black print from print >25 to print 250;
4 = medium toned image at print <25 but completely black print from print >50 to print 250;
5 = complete clean background throughout the complete print run

The results in Table 6 show that using a single-step post-anodic treatment (only a PVPA treatment) no proper clean-out of the plate can be obtained after storage under warm and humid conditions indicating a bad shelf life of the plate. When first a ZAT post-anodic treatment and then a PVPA post-anodic treatment is carried out, the clean-out performance after storage under warm and humid conditions is maintained at 5 indicating a good shelf life.

1-9. (canceled)

10. A method for making a lithographic printing plate precursor comprising the steps of:
(i) providing a grained and anodized aluminum support;
(ii) treating the support with an aqueous solution comprising a salt of zirconium;
(iii) treating the support with an aqueous solution comprising a compound comprising a phosphonic acid group and/or an ester or a salt thereof;
(iv) applying a coating comprising hydrophobic particles and a binder; and
(v) drying said coating.

11. The method according to claim 10, wherein the hydrophobic particles have an average particle diameter ranging between 20 nm and 55 nm, and wherein the amount of hydrophobic particles relative to the total weight of ingredients present in an imaging layer of the precursor is at least 70%.

12. The method according to claim 10, wherein the salt of zirconium is an alkali metal salt of hexafluorozirconate.

13. The method according to claim 11, wherein the salt of zirconium is an alkali metal salt of hexafluorozirconate.

14. The method according to claim 10, wherein the compound is a polymer comprising a repeating structural unit which comprises the phosphonic acid group and/or an ester or a salt thereof.

15. The method according to claim 14, wherein the polymer is polyvinylphosphonic acid.

16. The method according to claim 10, wherein the support has a Ra value below 0.45 μm and an anodic weight ≧3.2 g/m².

17. The method according to claim 11, wherein the support has a Ra value below 0.45 μm and an anodic weight ≧3.2 g/m².

18. A method for making a lithographic printing plate comprising the steps of:
(i) providing a printing plate precursor according to the method of claim 10;
(ii) exposing said printing plate precursor to light and/or heat;
(iii) optionally developing said exposed precursor by applying a processing liquid.

19. The method according to claim 18, further comprising developing said exposed precursor by applying a gum solution thereto.

20. A method of printing comprising the steps of:
(i) providing a printing plate precursor according to the method of claim 10;
(ii) exposing said printing plate precursor to light and/or heat;
(iii) optionally developing said exposed precursor by applying a processing liquid; and
(iv) mounting the obtained printing plate on a printing press and supplying ink and/or fountain.

21. The method according to claim 20, further comprising developing said exposed precursor by applying a gum solution thereto.
